(19) United States
(12) Patent Application Publication
(10) Pub. No.: US 2025/0364428 A1
(43) Pub. Date: Nov. 27, 2025

(54) SEMICONDUCTOR DEVICE

(71) Applicant: Mitsubishi Electric Corporation, Tokyo (JP)

(72) Inventors: Kaito HAMASAKI, Tokyo (JP); Shin SUZUKI, Tokyo (JP); Toshiya TADAKUMA, Tokyo (JP)

(73) Assignee: Mitsubishi Electric Corporation, Tokyo (JP)

(21) Appl. No.: 19/082,314

(22) Filed: Mar. 18, 2025

(30) Foreign Application Priority Data
May 22, 2024 (JP) 2024-083153

(51) Int. Cl. H01L 23/544

(52) U.S. Cl. CPC H01L 23/544; H01L 2223/54433

(57) ABSTRACT

An erroneous mounting of a standard type semiconductor module and a mirror type semiconductor module is prevented. A semiconductor device includes a standard type semiconductor module and a mirror type semiconductor module disposed side by side in a first direction. An identification mark is provided to an upper surface of a package of at least one of the standard type semiconductor module and the mirror type semiconductor module. The identification mark is located to be displaced in the first direction and a second direction perpendicular to the first direction from a center of the package.

### BACKGROUND

### Technical Field

The present disclosure relates to a semiconductor device to which a plurality of semiconductor modules are mounted.

### Description of the Background Art

For example, in a semiconductor module (also referred to as “a power module”) for controlling electrical power, the same product is parallelly connected to ensure an output capacity to be needed in some cases.

For example, Japanese Patent Application Laid-Open No. 2007-035670 discloses a semiconductor device having a structure that two semiconductor modules having a package shape symmetrical to each other are disposed side by side to be parallelly connected.

### SUMMARY

From a viewpoint of facilitating wiring, manufactured as the semiconductor module in some cases are a product of a standard type package (referred to as “a standard type semiconductor module” hereinafter) and a product of a mirror type package (referred to as “a mirror type semiconductor module” hereinafter) having a structure line-symmetric with respect to the standard type package (a structure that the standard type package is horizontally inverted). When the standard type semiconductor module and the mirror type semiconductor module are incorporated into the same semiconductor device, there is a possibility that an operator or an operation apparatus (simply referred to as “an operator” hereinafter) erroneously mounts the standard type semiconductor module and the mirror type semiconductor module.

An object of the present disclosure is to prevent an erroneous mounting of a standard type semiconductor module and a mirror type semiconductor module.

A semiconductor device according to the present disclosure includes a standard type semiconductor module and a mirror type semiconductor module disposed side by side in a first direction. An identification mark is provided to an upper surface of a package of at least one of the standard type semiconductor module and the mirror type semiconductor module. The identification mark is located to be displaced in the first direction and a second direction perpendicular to the first direction from a center of the package.

According to the present disclosure, an erroneous mounting of the standard type semiconductor module and the mirror type semiconductor module can be prevented.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a top view illustrating a configuration of a semiconductor device according to an embodiment 1.

FIG. 2 is a top view illustrating a configuration of a semiconductor device according to an embodiment 2.

FIG. 3 is a top view illustrating a configuration of a semiconductor device according to an embodiment 3.

FIG. 4 is a top view illustrating a configuration of a semiconductor device according to an embodiment 4.

FIG. 5 is a top view illustrating a configuration of a semiconductor device according to an embodiment 5.

FIG. 6 is a top view illustrating a configuration of a semiconductor device according to an embodiment 6.

FIG. 7 is a top view illustrating a configuration of a semiconductor device according to an embodiment 7.

### DESCRIPTION OF THE PREFERRED EMBODIMENTS

### Embodiment 1

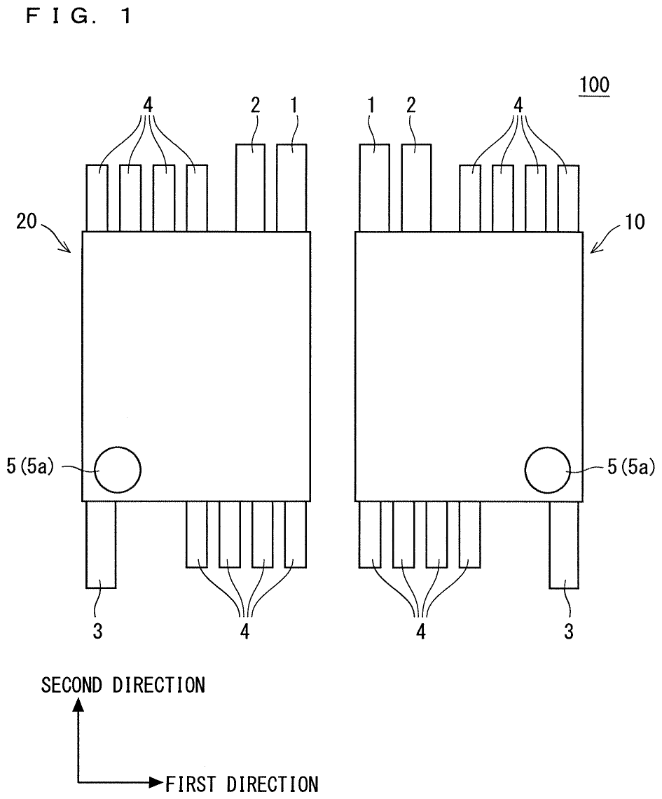

FIG. 1 is a top view illustrating a configuration of a semiconductor device 100 according to an embodiment 1. As illustrated in FIG. 1, the semiconductor device 100 has a structure that a standard type semiconductor module 10 and a mirror type semiconductor module 20 disposed side by side in a first direction are mounted on a substrate (not shown).

Each of the standard type semiconductor module 10 and the mirror type semiconductor module 20 includes a rectangular package with two sides parallel to the first direction and two sides parallel to a second direction perpendicular to the first direction, and also includes a P terminal 1 as a positive side input terminal, an N terminal 2 as a negative side input terminal, an AC terminal 3 as an alternating output terminal, and a plurality of control terminals 4. The mirror type semiconductor module 20 has a structure line-symmetric with respect to the standard type semiconductor module 10 in the first direction. That is to say, the structure of the mirror type semiconductor module 20 is the same as a structure of the standard type semiconductor module 10 inverted in the first direction.

An identification mark 5 indicating a direction of a package is provided to an upper surface of the package of at least one of the standard type semiconductor module 10 and the mirror type semiconductor module 20. In the embodiment 1, both the standard type semiconductor module 10 and the mirror type semiconductor module 20 include an identification mark 5a. The identification mark 5a is located to be displaced in the first direction and the second direction from a center of the package, and a position of the identification mark 5a in the standard type semiconductor module 10 and a position of the identification mark 5a in the mirror type semiconductor module 20 are line-symmetric in the first direction. That is to say, the position of the identification mark 5a in the mirror type semiconductor module 20 is the same as the position of the identification mark 5a in the standard type semiconductor module 10 inverted in the first direction.

In mounting the standard type semiconductor module 10 and the mirror type semiconductor module 20 to the semiconductor device 100 according to the present embodiment, an operator can distinguish the standard type semiconductor module 10 and the mirror type semiconductor module 20 in accordance with the position of the identification mark 5a. Accordingly, an erroneous mounting of the standard type semiconductor module 10 and the mirror type semiconductor module 20 is prevented.

Both the standard type semiconductor module 10 and the mirror type semiconductor module 20 include the identification mark 5. Thus, when a pair of the standard type semiconductor module 10 and the mirror type semiconductor module 20 constitutes one set configuration, the operator can easily identify a position and a direction of each set configuration, and such a configuration can contribute to prevention of erroneous mounting.

### Embodiment 2

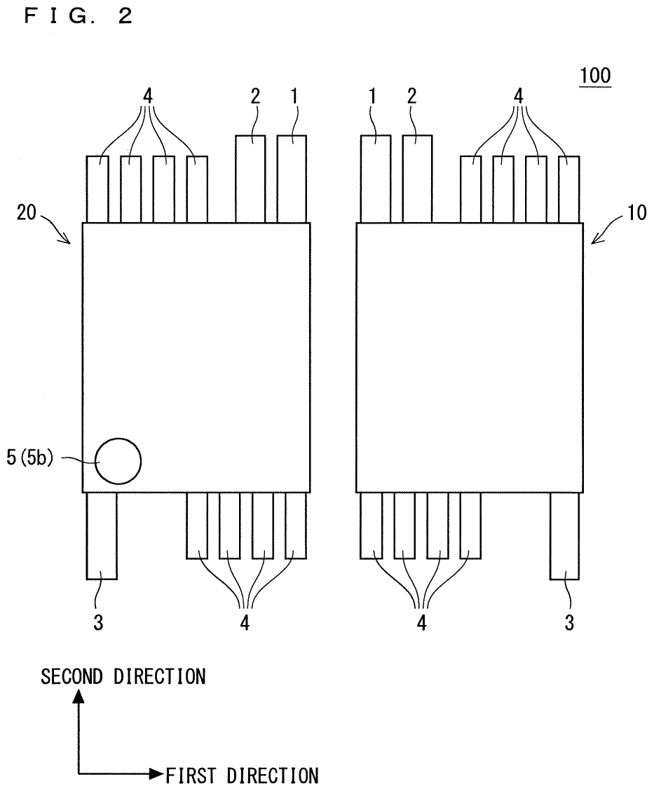

FIG. 2 is a top view illustrating a configuration of the semiconductor device 100 according to an embodiment 2. In FIG. 2, the same sign is assigned to the same or corresponding element as that illustrated in FIG. 1. Thus, the description thereof is omitted herein.

In the embodiment 2, only one of the standard type semiconductor module 10 and the mirror type semiconductor module 20 includes an identification mark 5b. Although FIG. 2 illustrates an example of providing the identification mark 5b to only the mirror type semiconductor module 20, the identification mark 5b may be provided to only the standard type semiconductor module 10. The identification mark 5b is located to be displaced in the first direction and the second direction from a center of the package.

In mounting the standard type semiconductor module 10 and the mirror type semiconductor module 20 to the semiconductor device 100 according to the present embodiment, an operator can distinguish the standard type semiconductor module 10 and the mirror type semiconductor module 20 in accordance with presence or absence of the identification mark 5b. Accordingly, an erroneous mounting of the standard type semiconductor module 10 and the mirror type semiconductor module 20 is prevented.

Only one of the standard type semiconductor module 10 and the mirror type semiconductor module 20 includes the identification mark 5b. Thus, when a pair of the standard type semiconductor module 10 and the mirror type semiconductor module 20 constitutes one set configuration, the operator can easily identify whether the standard type semiconductor module 10 and the mirror type semiconductor module 20 are correctly coupled in each set configuration, and such a configuration can also contribute to prevention of erroneous mounting.

### Embodiment 3

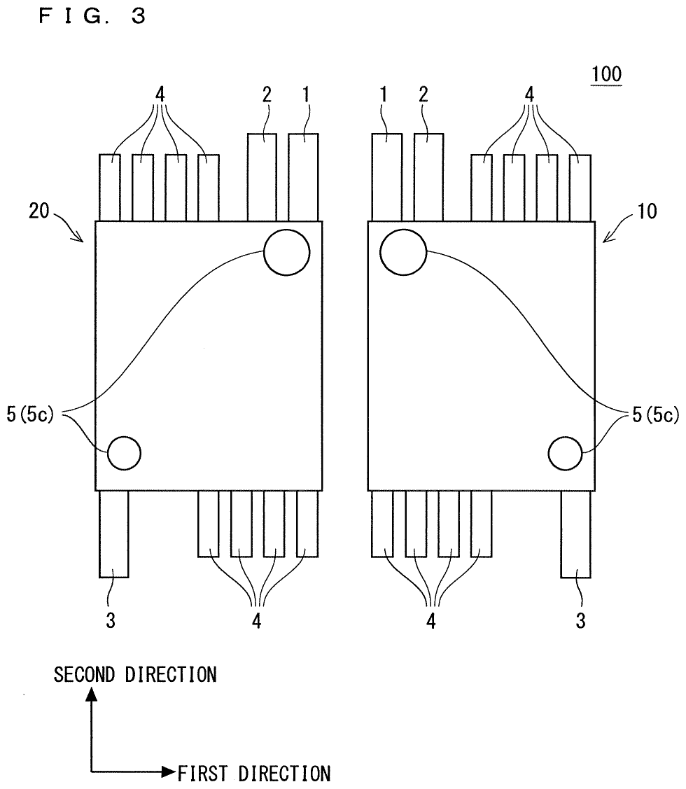

FIG. 3 is a top view illustrating a configuration of a semiconductor device 100 according to an embodiment 3. In FIG. 3, the same sign is assigned to the same or corresponding element as that illustrated in FIG. 1. Thus, the description thereof is omitted herein.

In the embodiment 2, each of the standard type semiconductor module 10 and the mirror type semiconductor module 20 includes a plurality of (two in FIG. 3) identification marks 5c with sizes or shapes different from each other. The identification mark 5c is located to be displaced in the first direction and the second direction from the center of the package, and positions of the plurality of identification marks 5c in the standard type semiconductor module 10 and positions of the plurality of identification marks 5c in the mirror type semiconductor module 20 are line-symmetric in the first direction. That is to say, the positions of the plurality of identification marks 5c in the mirror type semiconductor module 20 are the same as the positions of the plurality of identification marks 5c in the standard type semiconductor module 10 inverted in the first direction.

In mounting the standard type semiconductor module 10 and the mirror type semiconductor module 20 to the semiconductor device 100 according to the present embodiment, an operator can distinguish the standard type semiconductor module 10 and the mirror type semiconductor module 20 in accordance with the positions of the plurality of identification marks 5c with the sizes or the shapes different from each other. Accordingly, an erroneous mounting of the standard type semiconductor module 10 and the mirror type semiconductor module 20 is prevented.

### Embodiment 4

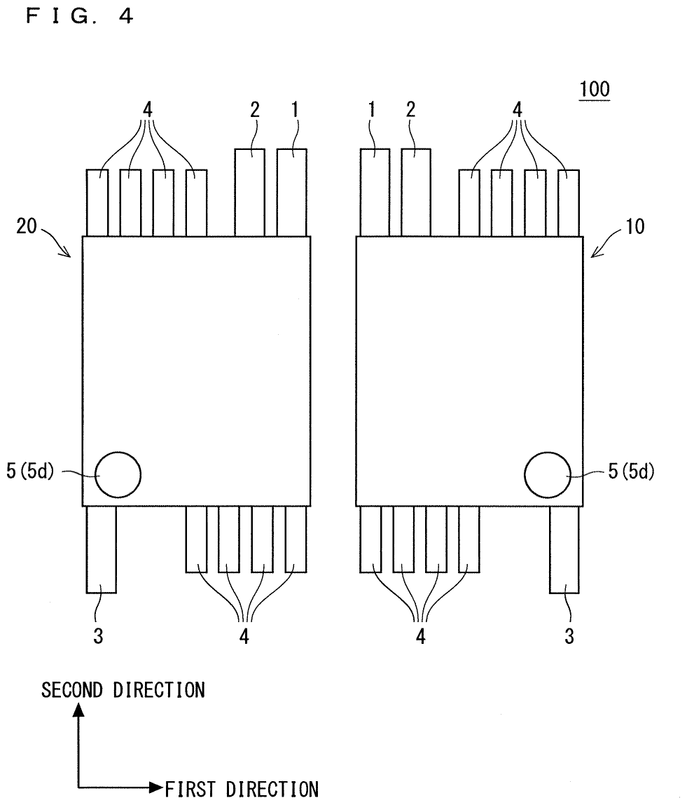

FIG. 4 is a top view illustrating a configuration of a semiconductor device 100 according to an embodiment 4. In FIG. 4, the same sign is assigned to the same or corresponding element as that illustrated in FIG. 1. Thus, the description thereof is omitted herein.

In the embodiment 4, both the standard type semiconductor module 10 and the mirror type semiconductor module 20 include an identification mark 5d with a concave shape. That is to say, the identification mark 5d is a concave part formed in the package. Used as the identification mark 5d with the concave shape is a mark of a pin (referred to as “a process mark” hereinafter) formed in the package when the package is pulled up from a mold using the pin after the package is formed of mold resin. That is to say, the identification mark 5d is formed by leaving the process mark in a desired position in the package. Thus, the identification mark 5d can be formed without increasing the number of processes of manufacturing the standard type semiconductor module 10 and the mirror type semiconductor module 20.

Herein, a size of a general process mark is approximately 0.1 mm in depth and 2 mm in diameter. Thus, it is preferable that the identification mark 5d with the concave shape does not have a size of 0.1 mm in depth and 2 mm in diameter so as to be distinguishable from the general process mark. For example, when a depth of the identification mark 5d is equal to or smaller than 0.05 mm or equal to or larger than 0.2 mm or a diameter of the identification mark 5d is equal or smaller than 1.5 mm or equal to or larger than 3 mm, the identification mark 5d and the general process mark can be distinguished from each other.

A method of forming the identification mark 5d is not limited to the method described above. Although the number of manufacturing processes is increased, the identification mark 5d may be formed by grinding the package, for example.

Although FIG. 4 illustrates the example that the arrangement of the identification mark 5d with the concave shape is the same as that of the identification mark 5a according to the embodiment 1 (FIG. 1), the identification mark 5d according to the embodiment 4 can also be applied to the embodiments 2 and 3.

### Embodiment 5

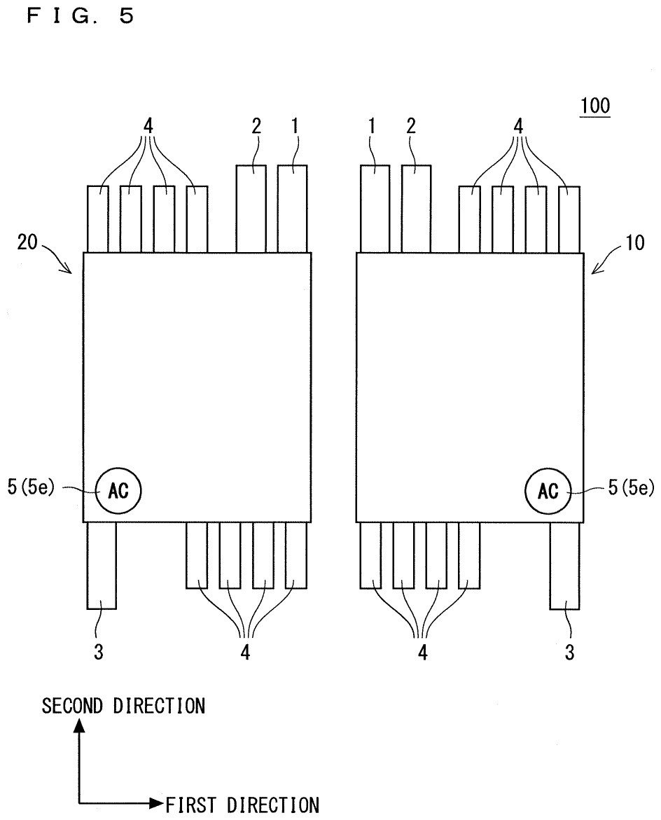

FIG. 5 is a top view illustrating a configuration of a semiconductor device 100 according to an embodiment 5. In FIG. 5, the same sign is assigned to the same or corresponding element as that illustrated in FIG. 1. Thus, the description thereof is omitted herein.

In the manner similar to the embodiment 4, both the standard type semiconductor module 10 and the mirror type semiconductor module 20 include an identification mark 5e with a concave shape. In the embodiment 5, a character or a graphic is printed in the identification mark 5e. Herein, the identification mark 5e is disposed near any terminal, and a character expressing the terminal located near the identification mark 5e is printed in the identification mark 5e. FIG. 5 illustrates an example that the identification mark 5e is disposed near an AC terminal 3, and a character of “AC” expressing the AC terminal 3 is printed in the identification mark 5e.

According to the present embodiment, the operator can obtain an effect that the terminal located near the identification mark 5e can be confirmed from the character or the graphic printed in the identification mark 5e in addition to the effect described in the embodiment 1, and the effect can also contribute to prevention of erroneous mounting of the standard type semiconductor module 10 and the mirror type semiconductor module 20.

Although FIG. 5 illustrates the example that the arrangement of the identification mark 5e in which the character or the graphic is printed is the same as that of the identification mark 5a according to the embodiment 1 (FIG. 1), the identification mark 5e according to the embodiment 5 can also be applied to the embodiments 2 and 3.

### Embodiment 6

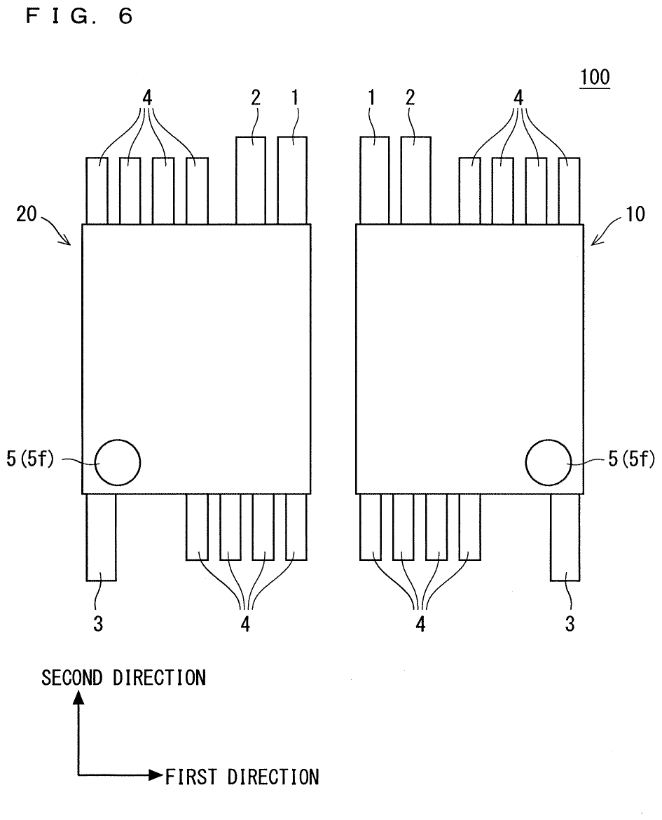

FIG. 6 is a top view illustrating a configuration of a semiconductor device 100 according to an embodiment 6. In FIG. 6, the same sign is assigned to the same or corresponding element as that illustrated in FIG. 1. Thus, the description thereof is omitted herein.

In the embodiment 6, both the standard type semiconductor module 10 and the mirror type semiconductor module 20 include an identification mark 5f with a convex shape. That is to say, the identification mark 5f is a convex part formed in the package.

The identification mark 5f has the convex shape, thus can be easily distinguished from a general process mark with a concave shape. Thus, the operator is prevented from erroneously recognizing the identification mark 5f as the process mark in mounting the standard type semiconductor module 10 and the mirror type semiconductor module 20 to the semiconductor device 100.

Although FIG. 6 illustrates the example that the arrangement of the identification mark 5f with the convex shape is the same as that of the identification mark 5a according to the embodiment 1 (FIG. 1), the identification mark 5f according to the embodiment 6 can also be applied to the embodiments 2 and 3.

### Embodiment 7

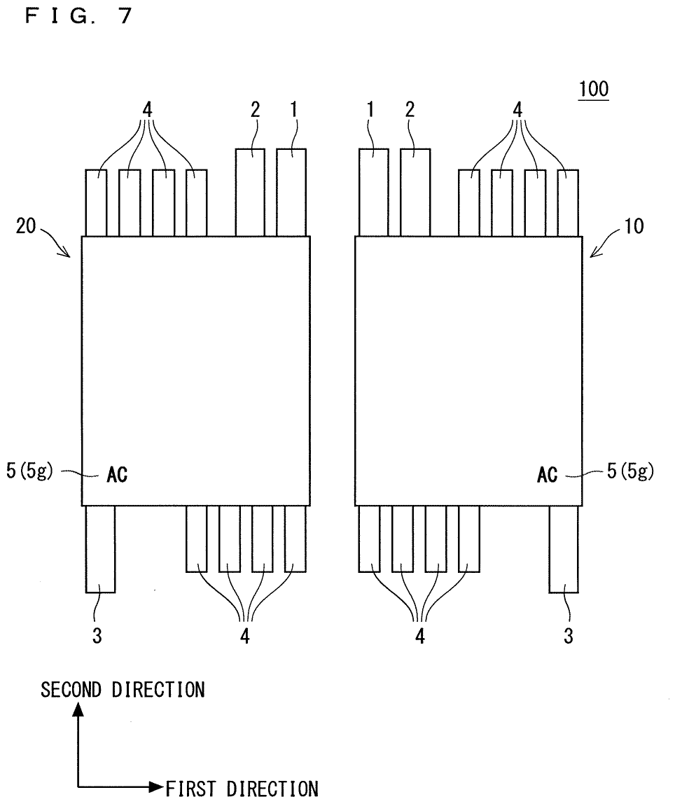

FIG. 7 is a top view illustrating a configuration of a semiconductor device 100 according to an embodiment 7. In FIG. 7, the same sign is assigned to the same or corresponding element as that illustrated in FIG. 1. Thus, the description thereof is omitted herein.

In the embodiment 7, both the standard type semiconductor module 10 and the mirror type semiconductor module 20 include an identification mark 5g made up of a character or a graphic printed in the package. Herein, the identification mark 5g is disposed near any terminal, and a character expressing the terminal near the identification mark 5g constitutes the identification mark 5g. In FIG. 7, the identification mark 5g is disposed near the AC terminal 3, and the character of “AC” expressing the AC terminal 3 constitutes the identification mark 5g.

According to the present embodiment, the operator can obtain an effect that the terminal located near the identification mark 5g can be confirmed from the character or the graphic constituting the identification mark 5g in addition to the effect described in the embodiment 1, and the effect can also contribute to prevention of erroneous mounting of the standard type semiconductor module 10 and the mirror type semiconductor module 20.

Although FIG. 7 illustrates the example that the arrangement of the identification mark 5g made up of the character or the graphic is the same as that of the identification mark 5a according to the embodiment 1 (FIG. 1), the identification mark 5g according to the embodiment 5 can also be applied to the embodiments 2 and 3.

Each embodiment can be arbitrarily combined, or each embodiment can be appropriately varied or omitted.

### APPENDIX

The aspects of the present disclosure are collectively described hereinafter as appendixes.

### Appendix 1

A semiconductor device, comprising
a standard type semiconductor module and a mirror type semiconductor module disposed side by side in a first direction, wherein
an identification mark is provided to an upper surface of a package of at least one of the standard type semiconductor module and the mirror type semiconductor module, and
the identification mark is located to be displaced in the first direction and a second direction perpendicular to the first direction from a center of the package.

### Appendix 2

The semiconductor device according to Appendix 1, wherein
both the standard type semiconductor module and the mirror type semiconductor module include the identification mark, and
a position of the identification mark in the standard type semiconductor module and a position of the identification mark in the mirror type semiconductor module are line-symmetric in the first direction.

### Appendix 3

The semiconductor device according to Appendix 1, wherein
only one of the standard type semiconductor module and the mirror type semiconductor module includes the identification mark.

### Appendix 4

The semiconductor device according to any one of Appendixes 1 to 3, wherein
a plurality of identification marks with sizes or shapes different from each other are provided to an upper surface of the package of at least one of the standard type semiconductor module and the mirror type semiconductor module.

### Appendix 5

The semiconductor device according to any one of Appendixes 1 to 4, wherein the identification mark is a concave part formed in the package.

### Appendix 6

The semiconductor device according to Appendix 5, wherein
a depth of the identification mark is equal to or smaller than 0.05 mm or equal to or larger than 0.2 mm.

### Appendix 7

The semiconductor device according to Appendix 5 or 6, wherein
a diameter of the identification mark is equal to or smaller than 1.5 mm or equal to or larger than 3 mm.

### Appendix 8

The semiconductor device according to any one of Appendixes 5 to 7, wherein
a character or a graphic indicating a terminal located near the identification mark is printed in the identification mark.

### Appendix 9

The semiconductor device according to any one of Appendixes 1 to 4, wherein the identification mark is a convex part formed in the package.

### Appendix 10

The semiconductor device according to any one of Appendixes 1 to 4, wherein the identification mark is a character or a graphic printed in the package.

### Appendix 11

The semiconductor device according to Appendix 10, wherein
the identification mark is a character or a graphic indicating a terminal located near the identification mark.

While the disclosure has been shown and described in detail, the foregoing description is in all aspects illustrative and not restrictive. It is therefore understood that numerous modifications and variations can be devised.

What is claimed is:

1. A semiconductor device, comprising:
a standard type semiconductor module and a mirror type semiconductor module disposed side by side in a first direction, wherein
an identification mark is provided to an upper surface of a package of at least one of the standard type semiconductor module and the mirror type semiconductor module, and
the identification mark is located to be displaced in the first direction and a second direction perpendicular to the first direction from a center of the package.

2. The semiconductor device according to claim 1, wherein
both the standard type semiconductor module and the mirror type semiconductor module include the identification mark, and
a position of the identification mark in the standard type semiconductor module and a position of the identification mark in the mirror type semiconductor module are line-symmetric in the first direction.

3. The semiconductor device according to claim 1, wherein
only one of the standard type semiconductor module and the mirror type semiconductor module includes the identification mark.

4. The semiconductor device according to claim 1, wherein
a plurality of identification marks with sizes or shapes different from each other are provided to an upper surface of the package of at least one of the standard type semiconductor module and the mirror type semiconductor module.

5. The semiconductor device according to claim 1, wherein
the identification mark is a concave part formed in the package.

6. The semiconductor device according to claim 5, wherein
a depth of the identification mark is equal to or smaller than 0.05 mm or equal to or larger than 0.2 mm.

7. The semiconductor device according to claim 5, wherein
a diameter of the identification mark is equal to or smaller than 1.5 mm or equal to or larger than 3 mm.

8. The semiconductor device according to claim 5, wherein
a character or a graphic indicating a terminal located near the identification mark is printed in the identification mark.

9. The semiconductor device according to claim 1, wherein
the identification mark is a convex part formed in the package.

10. The semiconductor device according to claim 1, wherein
the identification mark is a character or a graphic printed in the package.

11. The semiconductor device according to claim 10, wherein
the identification mark is a character or a graphic indicating a terminal located near the identification mark.
